(19) United States
(12) Patent Application Publication
(10) Pub. No.: US 2026/0337470 A1
(43) Pub. Date: Oct. 29, 2026

(54) Thermally Conductive Silicone Adhesive Composition

(71) Applicant: Henkel AG & Co. KGaA, Duesseldorf (DE)

(72) Inventors: Wenting Gao, Shanghai (CN); Yilei Zhu, Shanghai (CN); Jianying Chen, Shanghai (CN); Xingyu Zhu, Shanghai (CN); Yongming Li, Shanghai (CN)

(21) Appl. No.: 19/691,772

(22) Filed: May 29, 2026

Related U.S. Application Data
(63) Continuation of application No. PCT/CN2023/136645, filed on Dec. 6, 2023.

(51) Int. Cl. C09K 5/14; C09J 9/00; C09J 11/04; C09J 11/08; C09J 183/04; H10W 40/25

(52) U.S. Cl. CPC C09K 5/14; C09J 9/00; C09J 11/04; C09J 11/08; C09J 183/04; H10W 40/251

(57) ABSTRACT

A thermally conductive silicone adhesive composition having good flowability and cured gap stability and thermal conductivity, the composition comprising: (A) at least one alkenyl group-containing organopolysiloxane, (B) at least one chain-extender comprising terminal silicon-hydride, (C) at least one cross-linker comprising pendant silicon-hydride, (D) at least one catalyst, (E) at least one thermal conductive filler selected from aluminum oxide, aluminum nitride or a combination thereof, and (F) at least one core-shell solid polymer particle; wherein the mole ratio of component (B) to component (C) is from more than 1:1 to less than 10:1.

### TECHNICAL FIELD

The present invention relates to a thermally conductive silicone adhesive composition, specifically highlighting its excellent gap stability when cured, while preserving commendable thermal conductivity and good flowability.

### BACKGROUND OF THE INVENTION

Electronic components, like semiconductors and transistors, are designed to operate optimally at pre-determined temperatures, ideally aligned with the ambient air temperature. However, the operation of these components generates heat, and if not effectively dissipated, they can operate at temperatures well above the desired range. Excessive temperatures can adversely impact their performance and the overall device operation. To mitigate these issues, heat needs to be conducted away, typically through a heat sink. The heat sink can be cooled through traditional convection and/or radiation methods. During this process, the heat may transfer from the electrical component to the heat sink either through direct surface contact or via an intermediate medium, such as a thermal interface material (TIM).

Thermally conductive silicone gap fillers play a crucial role in TIM which provides effective thermal interfaces between heat sinks and electronic devices, accommodating for uneven surfaces, air gaps and rough surface textures. The thermally conductive gap filler's soft construction offers high conformability to reduce interface resistance. In addition to effective heat dissipation, they also help reduce vibration stress for shock dampening.

As electronic devices continue to evolve with size reduction and performance enhancement, the demand for thermally conductive gap fillers have risen, emphasizing key attributes such as gap stability, anti-vibration and shock performance. Notably, prior silicone gap fillers in the market have often faced challenges related to gap stability, such as slipping and cracking during application, compromising the device's heat-dissipating capacity.

In view of the above, it would be desirable to provide a thermally conductive silicone adhesive composition which exhibits excellent gap stability when cured, even in challenging conditions, ensuring a consistent flow rate without compromising thermal conductivity (>8 W/m·K).

### SUMMARY OF THE INVENTION

In one aspect, the present invention provides a thermally conductive silicone adhesive composition comprising:
(A) at least one alkenyl group-containing organopolysiloxane,
(B) at least one chain-extender comprising terminal silicon-hydride,
(C) at least one cross-linker comprising pendant silicon-hydride,
(D) at least one catalyst,
(E) at least one thermal conductive filler selected from aluminum oxide, aluminum nitride or a combination thereof, and
(F) at least one core-shell solid polymer particle;
wherein the mole ratio of component (B) to component (C) is from more than 1:1 to less than 10:1.

In another aspect, the present invention provides a cured product made from the thermally conductive composition according to the present invention.

In still another aspect, the present invention provides a method for preparing a thermally conductive gap filler according to the present invention.

In still another aspect, the present invention provides an article comprising the cured product made from the thermally conductive composition according to the present invention, or the thermally conductive gap filler made according to the present method.

In still another aspect, the present invention provides use of the thermally conductive silicone adhesive composition or the gap filler made from the same in manufacturing electronic devices, particularly in Insulate-Gate Bipolar Transistor (IGBT) module for power, and telecom and datacom devices, such as 5G station.

The advantages of the present invention include:
(1) the specific range mole ratio of the chain-extender comprising terminal silicon-hydride to cross-linker comprising pendant silicon-hydride enhances the stability of the resulting gap filler, particularly in terms of anti-vibration and shock resistance, while preserving thermal conductivity;
(2) adding solid core-shell polymer particle substantially enhances the stability of the resulting gap filler, even in challenging conditions, without compromising thermal conductivity; and
(3) the composition of the present invention has a good flowability with the thermally conductive filler loading of more than 86.3%.

### BRIEF DESCRIPTION OF DRAWINGS

FIG. 1 is the photo of the sample from Example 1 after high temperature aging test.

FIG. 2 is the photo of the sample from Comparative Example 3 after thermal circle test.

FIG. 3 is the photo of the sample from Comparative Example 2 after vibration and shock test.

FIG. 4A is the photo of the sample from Example 4 and FIG. 4B is the photo of the sample from Comparative Example 7, each after mixing before curing

### DETAILED DESCRIPTION OF THE INVENTION

It is to be understood by one of ordinary skill in the art that the present discussion is a description of exemplary embodiments only and is not intended as limiting the broader aspects of the present invention. Each aspect so described may be combined with any other aspect or aspects unless clearly indicated to the contrary. In particular, any feature indicated as being preferred or advantageous may be combined with any other feature or features indicated as being preferred or advantageous.

Unless specified otherwise, as used herein, the terms “a”, “an” and “the” include both singular and plural referents.

The terms “comprising” and “comprises” as used herein are synonymous with “including”, “includes”, “containing” or “contains”, and are inclusive or open-ended and do not exclude additional, non-recited members, elements or process steps.

Unless specified otherwise, the recitation of numerical end points includes all numbers and fractions subsumed within the respective ranges, as well as the recited end points.

Unless specified otherwise, all the term “room temperature” used herein refers to 23±2 °C.

Unless specified otherwise, all the molecular weights used herein refers to weight average molecular weights (Mw), which are obtained by gel permeation chromatography (GPC) according to DIN 55672.

Unless specified otherwise, all the “D₅₀ particle size” used herein represents a median diameter in a volume-basis particle size distribution curve obtained by measurement with a laser diffraction particle size analyzer.

Unless specified otherwise, all the parameters used herein are measured according to the methods as stated in the working examples of the present description, if any.

Unless otherwise defined, all terms used in disclosing the invention, including technical and scientific terms, have the meaning as commonly understood by one of the ordinary skills in the art to which this invention belongs.

In a first aspect, the present disclosure is generally directed to a thermally conductive silicone adhesive composition comprising:
(A) at least one alkenyl group-containing organopolysiloxane,
(B) at least one chain-extender comprising terminal silicon-hydride,
(C) at least one cross-linker comprising pendant silicon-hydride,
(D) at least one catalyst,
(E) at least one thermal conductive filler selected from aluminum oxide, aluminum nitride or a combination thereof, and
(F) at least one core-shell solid polymer particle;
wherein the mole ratio of component (B) to component (C) is from more than 1:1 to less than 10:1.
   (A) Alkenyl Group-Containing Organopolysiloxane composition comprises (A) an alkenyl group-containing organopolysiloxane.

Organopolysiloxane used herein also is called silicone oil. In the present invention, the component (A) organopolysiloxane carrying a reactive group, i.e. alkenyl group that can react with the reactive group, a —SiH group, in component (B) and (C).

As used herein, “alkenyl” refers to a radical of a straight-chain or branched hydrocarbon group having from 2 to 40 carbon atoms and one or more carbon-carbon double bonds (e.g., 1, 2, 3, or 4 double bonds) (“C₂₋₄₀ alkenyl”). In some embodiments, an alkenyl group has 2 to 30 carbon atoms (“C₂₋₃₀ alkenyl”). In some embodiments, an alkenyl group has 2 to 20 carbon atoms (“C₂₋₂₀ alkenyl”). In some embodiments, an alkenyl group has 2 to 10 carbon atoms (“C₂₋₁₀ alkenyl”). In some embodiments, an alkenyl group has 2 to 9 carbon atoms (“C₂₋₉ alkenyl”). In some embodiments, an alkenyl group has 2 to 8 carbon atoms (“C₂₋₈ alkenyl”). In some embodiments, an alkenyl group has 2 to 7 carbon atoms (“C₂₋₇ alkenyl”). In some embodiments, an alkenyl group has 2 to 6 carbon atoms (“C₂₋₆ alkenyl”). In some embodiments, an alkenyl group has 2 to 5 carbon atoms (“C₂₋₅ alkenyl”). In some embodiments, an alkenyl group has 2 to 4 carbon atoms (“C₂₋₄ alkenyl”). In some embodiments, an alkenyl group has 2 to 3 carbon atoms (“C₂₋₃ alkenyl”). In some embodiments, an alkenyl group has 2 carbon atoms (“C₂ alkenyl”). The one or more carbon-carbon double bonds can be internal (such as in 2-butenyl) or terminal (such as in 1-butenyl). Examples of C₂₋₄ alkenyl groups include ethenyl (C₂), 1-propenyl (C₃), 2-propenyl (C₃), 1-butenyl (C₄), 2-butenyl (C₄), butadienyl (C₄), and the like. Examples of C₂₋₆ alkenyl groups include the aforementioned C₂₋₄ alkenyl groups as well as pentenyl (C₅), pentadienyl (C₅), hexenyl (C₆), and the like. Additional examples of alkenyl include heptenyl (C₇), octenyl (C₈), octatrienyl (C₈), and the like. Unless otherwise specified, each instance of an alkenyl group is independently unsubstituted (an “unsubstituted alkenyl”) or substituted (a “substituted alkenyl”) with one or more substituents. In certain embodiments, the alkenyl group is an unsubstituted C₂₋₃₀ alkenyl. In certain embodiments, the alkenyl group is a substituted C₂₋₃₀ alkenyl.

In some embodiments, the quantity of alkenyl groups is within a range from 0.01 to 10 wt. %, and preferably from 0.1 to 5 wt. %, based on the total weight of the alkenyl group-containing organopolysiloxane.

In some embodiments, the viscosity at 25 °C of the component (A) is from 20 mPa·s to 1000 mPa·s, preferably from 40 mPa·s to 800 mPa·s. The viscosity herein was measured with TA Rheometer parallel plate using spindle 25 mm under 60 rpm, 25 °C.

There are no particular restrictions on the molecular structure of the component (A), including but being not limited to straight chain structures, cyclic structures, branched chain structures, partially branched straight chain structures and three-dimensional network structures. Furthermore, the component (A) may be a single polymer with this type of molecular structure, a copolymer with this type of molecular structure, or a mixture of different polymers with this type of molecular structure.

Specific examples of the component (A) include the compounds represented by the general formulae (i) to (v) shown as below.

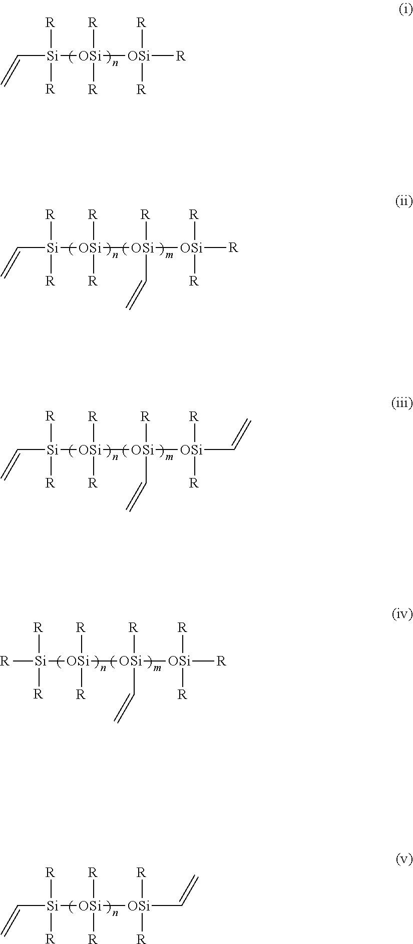

In the formulae (i) to (v) above, R each independently represents a substituted or unsubstituted monovalent hydrocarbon group bonded to a silicon atom, but excluding alkenyl groups, as described above, and is preferably a methyl group or a phenyl group. In the formulae (i) to (v), n is an integer of from 0 to 5000, m is an integer of from 5 to 5000, and the sum of n and m ranges from 5 to 10000. In some embodiments, n ranges from as little as 0, 10, 50, 100, 200, 500, as great as 1000, 2000, 5000, or within any range defined between any two of the foregoing values; and m ranges from 5, 10, 50, 200, or as great as 500, 1000, 2000, 5000, or within any range defined between any two of the foregoing values. In addition, the sum of n and m ranges from as little as 5, 10, 30, 50, 100, 200, 500, or great as 1000, 2000, 5000, 10000, or within any range defined between any two of the foregoing values, such as between 10 and 10000, and between 1000 and 5000.

In some embodiments, the unsubstituted or substituted monovalent hydrocarbon group R in the formulae (i) to (v) above is each independently selected from straight-chain alkyl groups, preferably selected from methyl group, ethyl group, n-propyl group, n-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-eicosyl group; branched-chain alkyl groups, preferably selected from isopropyl group, t-butyl group, isobutyl group, 2-methylundecyl group, and 1-hexylheptyl group; cyclic alkyl groups, preferably selected from a cyclopentyl group, cyclohexyl group, and cyclododecyl group; aryl groups, preferably selected from a phenyl group, tolyl group, and xylyl group; aralkyl groups, preferably selected from a benzyl group, phenethyl group, and 2-(2,4,6-trimethylphenyl) propyl group; and halogenated alkyl groups, preferably selected from 3,3,3-trifluoropropyl group and 3-chloropropyl group; preferably selected from straight-chain alkyl groups and aryl groups; and more preferably selected from methyl group, ethyl group and phenyl groups.

In one preferred embodiment, component (A) is selected from vinyl terminated polydimethylsiloxane, vinyl terminated diphenylsiloxane-dimethylsiloxane copolymer, vinyl terminated polyphenylsiloxane, vinylbenzyl terminated vinylphenylsiloxane-phenylmethylsiloxane copolymer, vinyl terminated trifluoropropylmethylsiloxane-dimethylsiloxane copolymer, vinyl terminated diethylsiloxane-dimethylsiloxane copolymer, vinylmethylsiloxane-dimethylsiloxane copolymer, trimethylsilanyl terminated vinylmethylsiloxane-dimethylsiloxane copolymer, silanol terminated vinylmethylsiloxane-dimethylsiloxane copolymer, vinylmethylsiloxane homopolymer, vinylmethylsiloxane copolymer, vinyl terminated poly(methyl siloxane) copolymer, vinyl terminated poly(methyl siloxane) copolymer, vinyl terminated poly (methyl siloxane) copolymer, poly(vinyl terminated poly(methyl siloxane) copolymer, poly (vinyl terminated poly(vinyl siloxane) and poly(vinyl siloxane) copolymer, monovinyl-terminated polydimethylsiloxane, vinylmethylsiloxane terpolymers, vinylmethoxysilane homopolymers, or combination thereof.

There are no particular restrictions on the molecular weight of component (A), and preferably in the range of from 3000 to 20,000 g/mol.

The component (A) may be used either alone, or in combinations of two or more different compounds.

Such alkenyl group-containing organopolysiloxane used as component (A) can be produced using conventionally known methods. In a typical production method, the alkenyl group-containing organopolysiloxane is produced by conducting an equilibration reaction of an organocyclooligosiloxane and a hexaorganodisiloxane in the presence of either an alkali or acid catalyst.

Examples of commercially available products of the component (A) include but are not limited to: vinyl terminated polydimethylsiloxane RH Vi70E RH Vi100E, RH Vi500E available from Zhejiang Runhe Chemical New Material Co., Ltd; and Andisil™ VS 20, Andisil™VS 50, Andisil™VS 100, Andisil™VS 200, Andisil™ VS 500, all of which are available from AB Specialty Silicones.

Preferably, the component (A) is present in an amount of from 0.5 to 6 wt. %, preferably 1 to 4.5 wt. %, such as 1.2, 1.5, 2.0, 2.5, 3.0, 3.5, 4.0, 4.5 wt. %, or any ranges between two numbers listed above, based on total weight of the composition.

### (B) Chain-Extender Comprising Terminal Silicon-Hydride

According to the present invention, the thermally conductive silicone adhesive composition comprises (B) a chain-extender comprising terminal silicon-hydride, to react with the alkenyl group in component (A) forming a linear, high molecular weight silicone polymer during curing.

Preferably, the component (B) does not comprise any pendant silicon-hydride.

Preferably, the component (B) has a structural formula:

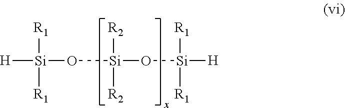

wherein R₁ each independently represents a substituted or unsubstituted alkyl group, aryl group, or hydrocarbon group having carbon atoms of from 1 to 3, R₂ each independently represents a substituted or unsubstituted alkyl group, aryl group, or hydrocarbon group having carbon atoms of from 1 to 10, and X represents an integer of from 0 to 5000.

As used herein, “alkyl” refers to a radical of a straight-chain or branched hydrocarbon group, such as methyl, ethyl, propyls, butyls and pentyls.

In some embodiments, the viscosity at 25 °C of the component (B) is lower than 1000 mPa·s, preferably lower than 500 mPa·s, and more preferably lower than 200 mPa·s. The viscosity herein was measured with TA Rheometer parallel plate using spindle 25 mm under 60 rpm, 25 °C. To obtaining desired processibility, the component (B) is preferably to have a viscosity of from 10 mPa's to 200 mPa·s.

Examples of commercially available products of the component (B) include, but are not limited to: DH02, DH04, DH07 available from Zhejiang Runhe Chemical New Material Co., Ltd; Andisil™ CE500 and 30LV available from AB silicones.

Preferably, the component (B) is present in an amount of from 0.01 to 3 wt. %, preferably 0.1 to 2 wt. %, such as 0.2, 0.4, 0.6, 0.8, 1.0, 1.5, 2.0 wt. %, or any ranges between two numbers listed above, based on total weight of the composition.

### (C) Cross-Linker Comprising Pendant Silicon-Hydride

According to the present invention, the thermally conductive silicone adhesive composition comprises (C) at least one cross-linker comprising pendant silicon-hydride, to react with the alkenyl group in component (A) forming a silicone matrix during curing. Introducing certain amount of component (C) not only promotes the cross-linking but also contributes to the overall integrity and performance of the gap filler made from the composition.

Preferably, the component (C) does not comprise any terminal silicon-hydride.

Preferably, the component (C) has a structural formula:

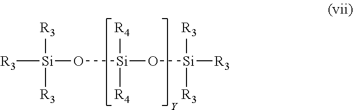

wherein R₃ each independently represents a substituted or unsubstituted alkyl group, aryl group, or hydrocarbon group having carbon atoms of from 1 to 3, R₄ each independently represents hydrogen, a substituted or unsubstituted alkyl group, aryl group, or hydrocarbon group having carbon atoms of from 1 to 10 provided that at least two of the R₄ are hydrogens, and Y represents an integer of from 0 to 5000.

In some embodiments, the viscosity at 25 °C of the component (C) is lower than 1000 mPa·s, preferably lower than 500 mPa·s, and more preferably lower than 200 mPa·s. The viscosity herein was measured with TA Rheometer parallel plate using spindle 25 mm under 60 rpm, 25 °C.

Examples of commercially available products of the component (C) include but are not limited to RH-H503, RH-H33, RH-H57, RH-H86 available from Zhejiang Runhe Chemical New Material Co., Ltd; Andisil™ XL1B, XL12, XL17 available from AB silicones.

Preferably, the component (C) is present in an amount of from 0.01 to 3 wt. %, preferably 0.05 to 1.5 wt. % by weight, such as 0.05, 0.1, 0.2, 0.3, 0.4, 0.5, 0.7, 1.0, 1.2, 1.5 wt. %, or any ranges between two numbers listed above, based on total weight of the composition.

According to the present invention, the mole ratio of the chain-extender comprising terminal silicon-hydride (B) to cross-linker comprising pendant silicon-hydride (C) of from more than 1:1 to less than 10:1, preferably from 2:1 to 8:1, such as 3:1, 4:1, 5:1, 6:1, 7:1, 8:1, 9:1, 9.5:1, or any ranges between two numbers listed above, can greatly improve the stability of the obtained gap filler especially anti-vibration and shock, without compromising the thermal conductivity. The gap filler made from the thermally conductive silicone adhesive composition without adding component (C) or adding not balanced ratio of component (B) to (C) would not survive the stability test under challenging conditions.

### (D) Catalyst

According to the present invention, the thermally conductive silicone adhesive composition comprises (D) a catalyst. An effective amount of the catalyst for catalyzing the hydrosilylation between the alkenyl group and —SiH group may be contained.

Preferably, a catalyst well-known as a catalyst used in a hydrosilylation reaction may be used. In a preferred embodiment of the present invention, the component (D) is a platinum-based catalyst. Examples of commercially available Pt catalyst include but are not limited to those available from Evonik, Gelest and Nusil. Preferably, the component (D) is Pt catalyst 540, with 0.2 wt. % Pt ratio, available from Evonik.

The effective amount of the catalyst is known for the skilled person in the art or can be determined by the skilled person in the art according to the reactants used. According to the present invention, the catalyst is preferably present in an amount of from 0.0005 to 0.1 wt. %, and preferably 0.001 to 0.05 wt. %, such as 0.004, 0.006, 0.008, 0.01, 0.015, 0.02, 0.025, 0.03, 0.035, 0.04, 0.045, 0.048 wt. %, or any ranges between two numbers listed above, based on the total weight of the composition.

### (E) Thermal Conductive Filler

According to the present invention, the thermally conductive silicone adhesive composition comprises (E) at least one thermal conductive filler selected from aluminum oxide, aluminum nitride or a combination thereof.

Herein, the “D₅₀ particle size” represents a median diameter in a volume-basis particle size distribution curve obtained by measurement with a laser diffraction particle size analyzer.

Preferably, the thermal conductive fillers with different particle sizes are mixed together as the component (e), that is, a big particle and a small particle are mixed together. For example, a big particle with a D50 particle size of at least 100 μm (such as 100-200 μm, 100-150 μm) and a small particle with a D50 particle size of less than 100 μm (such as 0.1-less than 100 μm, 1-50 μm, 1-30 μm) are mixed together as the component (e); a big particle with a D50 particle size of at least 50 μm (such as 50-200 μm, 50-150 μm) and a small particle with a D50 particle size of less than 50 μm (such as 0.1-less than 50 μm, 1-30 μm, 1-20 μm) are mixed together as the component (e); a big particle with a D₅₀ particle size of at least 30 μm (such as 30-200 μm, 30-150 μm) and a small particle with a D₅₀ particle size of less than 30 μm (such as 0.1-less than 30 μm, 1-less than 30 μm, 1-20 μm) are mixed together as the component (e); a big particle with a D₅₀ particle size of at least 10 μm (such as 10-200 μm, 10-150 μm) and a small particle with a D₅₀ particle size of less than 10 μm (such as 0.1-less than 10 μm, 1-less than 10 μm, 1-8 μm) are mixed together as the component (e).

According to the present invention, the types of the thermal conductive fillers shall be aluminum oxide, aluminum nitride or a combination thereof. The component (e) can be surface-treated or non-surface-treated ones, for example, (surface-treated) aluminium nitride, (surface-treated) aluminium oxide are mixed together as the component (e).

The shape of the thermal conductive fillers useful in the present application is not particularly limited. They may have spherical, tetrahedral, hexahedral, polyhedron, rod-like, needle-like, disk-like or irregular shape. In this description, the term “spherical” refers to a shape in which the entire surface is formed from a convex smooth surface. As for filler particles, the spheroidicity is, for example, 0.5 or higher, preferably 0.55 or higher and more preferably 0.6 or higher. The spheroidicity is an index indicating the degree close to a sphere. The spheroidicity of a sphere is 1. When the spheroidicity is high, such as in polyhedron shape, it increases the contact surfaces therefore easy for heat dissipating, and further when the spheroidicity is close to 1, it becomes easy for the filler particles to be dispersed in the silicone oil matrix. There is no particular limitation for the spheroidicity of the fillers.

In preferred embodiments, the thermally conductive filler is present in an amount of from 86.3% to 97% by weight, more preferably from 90% to 97% by weight, such as 90, 91, 92, 93, 94, 95, 96, 97 wt. %, or any ranges between two numbers listed above, based on the total weight of the composition.

In some embodiments, the component (E) comprises:
(e-1) aluminum oxide and/or aluminum nitride filler having a D50 particle size of from 50 μm to 200 μm,
(e-2) aluminum oxide and/or aluminum nitride filler having a D50 particle size of from no less than 10 μm to 30 μm,
(e-3) aluminum oxide and/or aluminum nitride filler having a D50 particle size of from 5 μm to 10 μm, and
(e-4) aluminum oxide and/or aluminum nitride filler having a D50 particle size less than 5 μm.
   (e-1) Aluminum Oxide and/or Aluminum Nitride Filler Having a D50 Particle Size of from 50 μm to 200 μm

In a preferred embodiment of the present invention, the component (e-1) has a D50 particle size of from 50 to 200 μm, preferably of from 60 μm to 160 μm, and more preferably of from 70 μm to 120 μm.

Examples of commercially available component (e-1) include but are not limited to BAK-70, BAK-90, BAK-120, TA F80 and TA F100 from Bestry.

Preferably, the component (e-1) is present in an amount of from 10 to 80% by weight, more preferably from 20 to 63% by weight, even more preferably from 30 to 55% by weight, and most preferably from 34 to 49% by weight, each based on the total weight of the composition.

(e-2) Aluminum Oxide and/or Aluminum Nitride Filler Having a D50 Particle Size of from No Less than 10 μm to 30 μm

In a preferred embodiment of the present invention, the component (e-2) has a D50 particle size of from no less than 10 μm to 30 μm, preferably of 12 μm to 30 μm, and more preferably of from 15 μm to 30 μm.

Examples of commercially available component (e-2) include but are not limited to: BAK-20 from Bestry, DAW-20 from Denka, AA-18 from Sumitomo and AN 30 from Ginet.

Preferably, the component (e-2) is present in an amount of from 5 to 70% by weight, more preferably from 15 to 50% by weight, even more preferably from 20 to 45% by weight, and most preferably from 25 to 40% by weight, each based on the total weight of the composition.

(e-3) Aluminum Oxide and/or Aluminum Nitride Filler Having a D50 Particle Size of from 5 μm to 10 μm

In a preferred embodiment of the present invention, the component (e-3) has a D50 particle size of from 5 μm to 10 μm, preferably from 5 μm to 8 μm.

Examples of commercially available component (e-3) include but are not limited to BAK5, BAK10 from Bestry; DAW-05, DAW-07 from Denka and AA-5, AA-10 from Sumitomo.

Preferably, the component (e-3) is present in an amount of from 1 to 40% by weight, more preferably from 10 to 30% by weight, each based on the total weight of the composition.

(e-4) Aluminum Oxide and/or Aluminum Nitride Filler Having a D50 Particle Size of Less than 5 μm

In a preferred embodiment of the present invention, the component (e-4) has a D50 particle size of less than 5 μm, preferably from 0.1 μm to 3 μm, more preferably from 0.1 μm to 2.5 μm.

In some embodiments, the component (e-4) comprises one aluminum oxide and/or aluminum nitride filler having a D50 particle size of less than 1 μm.

In some embodiments, the component (e-4) comprises one aluminum oxide and/or aluminum nitride filler having a D50 particle size of less than 1 μm and one aluminum oxide and/or aluminum nitride filler having a D50 particle size of from 1 μm to less than 5 μm.

Examples of commercially available component (e-4) include but are not limited to aluminum oxide and/or aluminum nitride filler having a D50 particle size of from 0.1 μm to 0.5 μm, such as AA-03, AA-03F, AA-03NF, AA-04, AA-05 from Sumitomo and ASFP-03S, ASFP-05S from Denka; aluminum oxide and/or aluminum nitride filler having a D50 particle size of from 0.6 μm to 2 μm, such as BAK-1, NSM-1S, NSM-2S, TA F01, TA F02 from Bestry, AN 2 from Ginet and AlN020RW from Thurtek.

Preferably, the component (e-3) is present in an amount of from 1 to 40% by weight, more preferably from 10 to 30% by weight, each based on the total weight of the composition.

In a preferred embodiment of the present invention, the thermally conductive silicone adhesive composition according to the present invention contains no filler except the component (E).

### (F) Core-Shell Solid Polymer Particle

According to the present invention, the thermally conductive silicone adhesive composition comprises (F) at least one core-shell solid polymer particle.

Preferably, the component (F) has a soft core formed by a polymer having a Tg of less than 0 °C especially less than-20 °C, (hereinafter abbreviated as core-polymer) and the hard shell is formed by a polymer having a Tg of no less than 0 °C, especially no less than 20 °C, (hereinafter abbreviated as shell-polymer).

The core-shell solid polymer particle useful in the composition of the present application is in a solid state during the formulation and preparation of the gap filler and does not react with the silicone oil matrix. The core-shell solid polymer is physically mixed in the composition rather than crosslinks with the silicone oil.

The Tg of the core-polymer or of the shell-polymer can be roughly calculated based on the monomers used for forming the polymer according to the FOX equation, and also can be determined using differential scanning calorimetry (DSC) based on the known method in the art.

1/Tg=W1/Tg1+W2/Tg2+ . . . Wn/Tgn (FOX equation)

### Wherein:

Tg is the glass transition temperature of the polymer,
W1 is weight percentage of the first monomer, wt. %
Tg1 is the Tg of the first monomer,
W2 is weight percentage of the second monomer, wt. %
Tg2 is the Tg of the second monomer;
Wn is weight percentage of the nth monomer, wt. %
Tgn is the Tg of the nth monomer.

The core-polymer of the present application can be a homopolymer or copolymer, as long as the Tg of the polymer satisfies the above limitation, that is, less than 0 °C, such as less than −5 °C, less than −10 °C, less than −15 °C, less than −20 °C, less than −25 °C, less than −30 °C, less than −35 °C, less than −40 °C, less than −45 °C, less than −50 °C.

It is not necessary that all monomers of the core-polymer have a Tg of less than 0 °C, as long as the obtained core-polymer has Tg of less than 0 °C. It is preferred that all monomers of the core-polymer have a Tg of less than 0 °C.

In preferred embodiments, the core-polymer may be a homopolymer or copolymer formed from monomers like dienes, alkyl (meth)acrylates, silicone rubbers, styrenics and mixtures thereof. Specific examples of the dienes monomer include, but not limited to, butadiene and isoprene. For example, the core-polymer can be a butadiene homopolymer, an isoprene homopolymer, a silicone rubber, a coplymer of butadiene or isoprene with one or more ethylenically unsaturated monomers (such as vinyl aromatic monomers, (meth)acrylonitrile, (meth)acrylates, or the like). Specific examples of alkyl (meth)acrylates include, but not limited to, methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, amyl (meth)acrylate, isoamyl (meth)acrylate, n-hexyl (meth)acrylate, cycloheyl (meth)acrylate, 2-ethylhexyl (meth)acrylate, pentadecyl (meth)acrylate, dodecyl (meth)acrylate, isobornyl (meth)acrylate, penyl (meth)acrylate, benzyl (meth)acryate, phenoxyethy (meth)acrylate, 2-hydroxyethyl (meth)acrylate and 2-methoxyethyl (meth)acrylate. Specific examples of styrenics include, but not limited to, alpha-methyl styrene and para-methyl styrene. In particulre, the core-polymer can be a silicone rubber, Methyl methacrylate-Butadiene-Styrene (MBS) tripolymer, or alkyl acrylates polymer.

The shell-polymer of the present application can be a homopolymer or copolymer, as long as the Tg of the shell-polymer satisfies the above limitation, that is, no less than 0 °C, such as no less than 5 °C, no less than 10 °C, no less than 15 °C, no less than 20 °C, no less than 25 °C, no less than 30 °C, no less than 35 °C, no less than 40 °C, no less than 45 °C, no less than 50 °C, no less than 80 °C, no less than 100 °C.

It is not necessary that all monomers of the shell-polymer have a Tg of no less than 0 °C, as long as the obtained shell-polymer has Tg of no less than 0 °C. It is preferred that all monomers of the core-polymer have a Tg of no less than 0 °C.

In preferred embodiments, the shell-polymer may be a homopolymer or copolymer formed from monomers like methacrylates, acrylates, styrenics and mixtures thereof.

Specific examples of methacrylates for the shell-polymer include, but are not limited to, methyl methacrylate, ethyl methacrylate, n-propyl methacrylate, isopropyl methacrylate, n-butyl methacrylate, isobutyl methacrylate, sec-butyl methacrylate, tert-butyl methacrylate, amyl methacrylate, isoamyl methacrylate, n-hexyl methacrylate, cyclohexyl methacrylate, 2-ethylhexyl methacrylate, pentadecyl methacrylate, dodecyl methacrylate, isobornyl methacrylate, phenyl methacrylate, benzyl methacrylate, phenoxyethyl methacrylate, 2-hydroxyethyl methacrylate and 2-methoxyethyl methacrylate.

Specific examples of acrylates for the shell-polymer include, but are not limited to, methyl acrylate, ethyl acrylate, n-propyl acrylate, isopropyl acrylate, n-butyl acrylate, isobutyl acrylate, sec-butyl acrylate, tert-butyl acrylate, amyl acrylate, isoamyl acrylate, n-hexyl acrylate, cycloheyl acrylate, 2-ethylhexyl acrylate, pentadecyl acrylate, dodecyl acrylate, isobornyl acrylate, phenyl acrylate, benzyl acrylate, phenoxyethyl acrylate, 2-hydroxyethyl acrylate and 2-methoxyethyl acrylate. Preferably the acrylate ester monomers are chosen from methyl acrylate, ethyl acrylate, n-butyl acrylate, 2-ethylhexyl acrylate and octyl acrylate.

Specific examples of styrenics for the shell-polymer include, but are not limited to, styrene, and derivatives thereof such as, but not limited to, alpha-methyl styrene, and para-methyl styrene.

In particular, the shell-polymer comprises (or is) poly(methyl methacrylate) (PMMA).

The core constitutes 50-95 wt. % of the core-shell particle, and the shell constitutes 5-50 wt. % of the core-shell particle.

Preferably, the core-shell particles are relatively small in size. For example, the D₅₀ particle size may be from about 0.03 μm to about 5 μm or from about 0.05 μm to about 4 μm, or from 60 nm to 3 μm, or from 70 nm to 2 μm, or from 75 nm to 1 micron, such as 35 nm 40 nm, 55 nm, 65 nm, 80 nm, 90 nm, 1 μm, 1.2 μm, 1.4 μm, 1.6 μm, 1.8 μm, 2.0 μm, 2.2 μm, 2.4 μm, 2.6 μm, 2.8 μm, 3.0 μm, 3.2 μm, 3.4 μm, 3.6 μm, 3.8 μm, 4.0 μm, 4.2 μm, 4.4 μm, 4.6 μm and 4.8 μm, or any ranges between two numbers listed above. The term “D₅₀ particle size” means a median diameter in a volume-basis particle size distribution curve obtained by measurement with a laser diffraction particle size analyzer.

The core-shell polymer can be produced by any known technique, for example, by two-step emulsion or dispersion polymerization, for example, the core monomers are polymerized in aqueous dispersion or emulsion and then the shell monomers are polymerized onto the formed core-polymer.

The ratio in thickness of the soft core part and the hard shell part of the core-shell polymer particles used herein is not particularly limited, and the thickness ratio may be general one of the core part to the shell part formed in a usual manner by, for example, an emulsion polymerization method.

The commercially available core-shell solid polymer particles useful in the present application include, but not limited to, SX-005 from Mitsubishi Chemical Corporation, M500S from Shanghai Bangdi Mew Materials Co. Ltd., M960 from Anqiu Donghai Plastic Industry Co., Ltd, PARALOID™ EXL-2300 and PARALOID™ EXL-2330 from Dow Chemical.

Conventional tougheners or impact modifiers cannot be well mixed into the silicone oil matrix of the present application and usually form a mixture with separate phases, while the core-shell solid polymer particle mentioned above can be well blended into the silicone oil matrix and do not negatively affect the cross-linking of the silicone oils, and importantly, can impart anti-vibration and shock to the cured thermally conductive product. Meanwhile, only small amount of the core-shell solid polymer particle can greatly improve the stability of the cured product.

According to the present application, the core-shell solid polymer particle can be contained in the composition in an amount of from 0.01 wt. % to less than 0.7 wt. %, preferably 0.1 to 0.6 wt. %, such as 0.1, 0.15, 0.2, 0.25, 0.30, 0.35, 0.40, 0.45, 0.50, 0.55, 0.60 wt. %, or any ranges between two numbers listed above, based on the total weight of the composition.

### Optional Components

In some embodiments of the present invention, the thermally conductive silicone adhesive composition according to the present invention may further optionally comprise additives which are commonly used in the art to which the present invention belongs, such as inhibitors, non-reactive organopolysiloxane, filler treatment agent, pigments, dyes, fluorescent dyes, heat resistant additives, flame retardants, plasticizers, adhesion-imparting agents and combinations thereof, as long as they do not negatively affect the desired technical effects of the inventive composition. The presence, the type and the amount of the additive can be determined by a specialist in the art according to actual requirements.

In some embodiments, inhibitors are added to control the reaction speed, because hydrosilylation with catalyst has very fast reaction kinetics. Alkynol type curing inhibitors and other inhibitors that are conventionally used in the art can be used in the present application.

Specific examples of the inhibitors include alkynols such as 3-butyn-2-ol, 1-pentyn-3-ol, 1-hexyn-3-ol, 1-heptyn-3-ol, 5-methyl-1-hexyn-3-ol, 3,5-dimethyl-1-hexyn-3-ol, 1-ethynyl-1-cyclopentanol, 1-ethynyl-1-cyclohexanol, 1-ethynyl-1-cycloheptanol, 3-ethyl-1-hexyn-3-ol, 3-ethyl-1-heptyn-3-ol, 3-isobutyl-5-methyl-1-hexyn-3-ol, 3,4,4-trimethyl-1-pentyn-3-ol, 3-ethyl-5-methyl-1-heptyn-3-ol, 4-ethyl-1-octyn-3-ol, 3,7,11-trimethyl-1-dodecyn-3-ol, 1-ethynyl-1-cyclooctanol, 3-methyl-1-octyn-3-ol, 3-methyl-1-nonyn-3-ol, 3-methyl-1-decyn-3-ol, 3-methyl-1-dodecyn-3-ol, 3-ethyl-1-pentyn-3-ol; a hydrazine-based compound; a phosphine-based compound; multi-vinylpolysiloxanes or a mercaptan-based compound.

Suitable commercially available examples of the inhibitor include Inhibitor MVC from Evonik and 3,5-dimethyl-1-hexyn-3-ol from Sigma-Aldrich Company.

In the present application, when the requirements of preparation, transportation, storage or formulation time can be satisfied without adding the inhibitor, the inhibitor can be omitted.

When the inhibitor is present in the composition of the present application, the amount thereof can be adjusted by the skilled person in the art according to requirements without particular limitation. For example, an amount of 0.0001 to 1.0 wt. %, preferable 0.001 to 0.5 wt. %, such as 0.01, 0.02, 0.03, 0.04, 0.05, 0.07, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95 wt. %, or any ranges between two numbers listed above, of the inhibitor can be contained in the composition of the present application, based on the total weight of the composition.

In some embodiments, the thermally conductive silicone adhesive composition optionally comprises non-reactive organopolysiloxane which are added for adjusting flow rate.

Dimethylpolysiloxane, methylphenylsiloxane and (methyl-3,3,3-trifluoropropyl) siloxane that are conventionally used in the art can be used in the present application.

In the present application, when the requirements of preparation, transportation, storage or formulation time can be satisfied without adding the non-reactive organopolysiloxane, the non-reactive organopolysiloxane can be omitted.

Suitable commercially available examples of the non-reactive organopolysiloxane include H201-20, H201-50, H201-100, H201-200, H201-500 from Sinopharm, Andisil™ SF 20, Andisil™ SF 50, Andisil™ SF 100, Andisil™ SF 200, Andisil™ SF 500 from AB specialty silicone.

When the non-reactive organopolysiloxane is present in the composition of the present application, the amount thereof can be adjusted by the skilled person in the art according to requirements without particular limitation. For example, an amount of 0.01 to 5.0 wt. %, preferable 0.01 to 4.5 wt. %, such as 0.02, 0.08, 0.2, 0.6, 0.8, 1.0, 1.2, 1.5, 1.7, 1.9, 2.1, 2.3, 2.5, 2.7, 3.0, 3.3, 3.6, 3.9. 4.2, 4.4 wt. %, or any ranges between two numbers listed above, of the non-reactive organopolysiloxane can be contained in the composition of the present application, based on the total weight of the composition.

In some embodiments, the thermally conductive silicone adhesive composition optionally comprises filler treatment agent, such as linear trimethoxymethylsilane-terminated polysiloxane, which ensures fillers effectively dispersed within the polymer matrix, improves adhesion, and optimizes heat transfer capabilities. The linear structure enhances flexibility and compatibility, while terminally bound trimethoxymethylsilane groups allow for tailored surface modifications.

Suitable commercially available examples of the filler treatment agent include linear trimethoxymethylsilane terminated polysiloxane having a viscosity of 30 mPa·s available from Henkel.

When the filler treatment agent is present in the composition of the present application, the amount thereof can be adjusted by the skilled person in the art according to requirements without particular limitation. For example, an amount of 0.01 to 5.0 wt. %, preferable 0.01 to 2.5 wt. %, such as 0.02, 0.04, 0.06, 0.08, 0.1, 0.2, 0.3, 0.4, 0.5, 0.6, 0.7, 0.8, 0.9, 1.0, 1.3, 1.5, 1.7, 1.9, 2.1, 2.3 wt. %, or any ranges between two numbers listed above, of the filler treatment agent can be contained in the composition of the present application, based on the total weight of the composition.

The composition of the present invention has many advantages over the prior art. First, the carefully defined mole ratio range between the chain-extender with terminal silicon-hydride and the cross-linker with pendant silicon-hydride serves to augment the stability of the resulting gap filler. This enhancement is particularly pronounced in terms of anti-vibration and shock resistance, while maintaining the thermal conductivity performance. This precise ratio not only contributes to the robustness of the material but also ensures its optimal performance in scenarios where resistance to vibrations and shocks is paramount; adding small amount of solid core-shell polymer particles in the composition plays a crucial role in fortifying the stability of the resulting gap filler. This reinforcement holds true even under challenging conditions, attesting to the material's resilience. Moreover, the composition maintains a consistent flow rate, a vital characteristic in various applications, without compromising the thermal conductivity of the gap filler. The inclusion of these solid core-shell polymer particles not only enhances the material's overall stability but also underscores its adaptability to adverse environmental conditions, making it a reliable choice for applications that demand enduring performance and thermal efficiency. Lastly, the composition of the present invention has a good flowability with the thermally conductive filler loading of more than 86.3%, for example, having a flow rate more than 30 g/min, preferably more than 35 g/min, defined as the adhesive composition weight dispensed under a pressure of 90 psi per minute using dispenser machine Nordson Ultimus-I equipped with a 30 cc plastic tube having a nozzle in a diameter of 2.54±5% mm.

According to the present invention, the thermally conductive silicone adhesive composition can be one-part or two-parts. The cured product of the thermally conductive silicone adhesive composition can be gap filler or gel exhibiting a flow rate of above 30 g/mol, preferably more than 35 g/min.

In another aspect, the present invention provides a cured product of the thermally conductive adhesive composition.

In another aspect, the present invention provides a method for preparing a thermally conductive gap filler, comprising.
(i) mixing the following components to form a mixture:
(A) at least one alkenyl group-containing organopolysiloxane;
(B) at least one chain-extender comprising terminal silicon-hydride;
(C) at least one cross-linker comprising pendant silicon-hydride;
(D) at least one catalyst;
(E) at least one thermal conductive filler selected from aluminum oxide, aluminum nitride or a combination thereof;
(F) a core-shell solid polymer particle, and
other optional components,
(ii) allowing the mixture to cure.

The thermally conductive silicone adhesive composition according to the present invention may be prepared by any conventional preparation methods in the art. Preferably, the composition according to the present invention may by prepared by mixing all the components therein at room temperature in a conventional mixing device, such as a planetary mixer or speedmixer.

In preferred embodiments, the composition can be cured at room temperature for no more than 7 days. Curing can be accelerated by applying heat, for example, by heating from 60 to 200 °C (such as 70 °C, 80 °C, 100 °C, 110 °C, 120 °C, 130 °C, 140 °C, 150 °C, 160 °C, 170 °C, 180 °C, 190 °C) for from 30 minutes to 2 hours.

In the present invention, the composition can be applied to the desired substrate by any convenient technique. It can be applied cold or be applied warm if desired. It can be applied by extruding or pasting it onto the substrate or other mechanical application methods such as a caulking gun. After application, the composition of the present invention is cured at room temperature, optionally followed by being curing at elevated temperature.

The composition of the present application can be made into gap filler for subsequent use. It is conceivable that the composition of the present application can be applied to any gap between two surfaces as an adhesive to bond the surfaces.

In another aspect, the present invention provides an article comprising the thermally conductive gap filler made from the composition according to the present invention.

In a third aspect, the present disclosure is directed to a use of the thermally conductive silicone adhesive composition or the gap filler made from the same in manufacturing electronic devices, particularly in Insulate-Gate Bipolar Transistor (IGBT) module for power, and telecom and datacom devices, such as 5G station and electric vehicles.

Exemplary electronic devices encompass computers and computer equipment, such as telecom and datacom devices, such as 5G station, Insulate-Gate Bipolar Transistor (IGBT) module for power, electric vehicles, printers, fax machines, scanners, keyboards and the like; medical sensors; automotive sensors and the like; wearable electronic devices (e.g., wrist watches and eyeglasses) and their integrated circuit elements, handheld electronic devices (e.g., phones (e.g., cellular telephones and cellular smartphones) and their integrated circuit elements, cameras, tablets, electronic readers, monitors (e.g., monitors used in hospitals, and by healthcare workers, athletes and individuals), watches, calculators, mice, touch pads, and joy sticks), computers (e.g., desk top and lap top computers) and their integrated circuit elements, computer monitors, televisions, media players, household appliances (e.g., refrigerators, washing machines, dryers, ovens, and microwaves), light bulbs (e.g., incandescent, light emitting diode, and fluorescent), and articles that include a visible transparent or transparent component, glass housing structures, protective transparent coverings for a display or other optical component.

### EXAMPLES

The following examples are intended to assist one skilled in the art to better understand and practice the present disclosure. The scope of the invention is not limited by the examples but is defined in the appended claims. All parts and percentages are based on weight unless otherwise stated.

### Raw Material

(A) Alkenyl group-containing organopolysiloxane-1: RH-Vi 500E from Zhejiang Runhe Chemical New Material Co., Ltd, which is an alkenyl group-containing organopolysiloxane having a viscosity of 500 mPa·s.
(A) Alkenyl group-containing organopolysiloxane-2: RH-Vi 100E from Zhejiang Runhe Chemical New Material Co., Ltd, which is an alkenyl group-containing organopolysiloxane having a viscosity of 100 mPa·s.
(B) Chain-extender comprising terminal silicon-hydride-1: DH 04 from Zhejiang Runhe Chemical New Material Co., Ltd, which is chain extender comprising terminal silicon-hydride having a viscosity of 100 mPa·s.
(B) Chain-extender comprising terminal silicon-hydride-2: Andisil CE-30LV from AB specialty silicone, which is chain extender comprising terminal silicon-hydride having a viscosity of 30 mPa·s.
(C) cross-linker comprising pendant silicon-hydride: Andisil XL1B from AB specialty silicone, which is a cross-linker comprising pendant silicon-hydride having a viscosity of 100 mPa·s.
(D) Catalyst: CATALYST 512, which is a divinyl tetramethyl disiloxane complex having 2% by weight of platinum, manufactured by Evonik.
(E) Aluminum oxide-1: AA-03NF having a D₅₀ particle size of 0.3 μm available from Sumitomo.
(E) Aluminum nitride-1: AlN020RW having a D₅₀ particle size of 1.5 μm available from Thurtek.
(E) Aluminum oxide-2: BAK5 having a D₅₀ particle size of 5 μm available from Bestry.
(E) Aluminum oxide-3: BAK20 having a D₅₀ particle size of 20 μm from Bestry.
(E) Aluminum nitrie-2: TAF100 having a D₅₀ particle size of 100 μm from Bestry.
Silica: CAB-O-SIL EH-5 from having a BET specific surface area is 360 m²/g from Cabot.
(F) Core-shell particle-1: SX-005 from Mitsubishi Chemical Corporation, which is a core-shell solid polymer particle with silicone rubber forming the core and MMA forming the shell.
(F) Core-shell particle-2: M500S from Shanghai Bangdi New Material Co., Ltd, which is a core-shell solid polymer particle with MBS forming the core and MMA forming the shell.
(F) Core-shell particle-3: M960 from Anqiu Donghai Plastic Industry Co., Ltd, which a core-shell solid polymer particle with acrylic resin forming the core and MMA forming the shell.
Dimethylpolysiloxane: H201-20 from Sinopharm.
Filler treatment agent: linear trimethoxymethylsilane terminated polysiloxane having a viscosity of 30 mPa·s available from Henkel.
Inhibitor: MVC, which is a silicone-based inhibitor manufactured by Evonik.

### Preparation of Examples 1-7 and Comparative Examples 1-7 (Ex. 1 to Ex. 7 and CE1 to CE7)

Specific amounts and types of components in the thermally conductive silicone adhesive compositions of Examples 1 to 7 and Comparative Examples 1 to 7 are shown in Tables 1 to 2 as below. The formulations were prepared by initially mixing all components, excluding catalyst and inhibitor, in a planetary mixer at room temperature. The blend underwent high-shear dispersion at 800 RPM for 1 hour, with thermal fillers added sequentially from small to large particle sizes under a vacuum of 0.1 MPa to remove air bubbles. Subsequently, the mixture was vacuum-mixed at 85 °C to 150 °C for one hour, followed by the addition of catalyst and inhibitor (if applicable) after cooling to room temperature. The final vacuum mixing lasted for 10 to 30 minutes, ensuring a uniform and well-prepared composition. The mixing equipment used was 1.5 L ROSS mixer made from Charles Ross & Son Company.

### Test Methods:

### Flow Rate

The flow rate of the thermally conductive silicone adhesive composition of the present invention and samples of the comparative examples were tested by a dispenser machine (Nordson Ultimus™-I). The dispenser machine contains a 30 cc plastic tube having a nozzle in a diameter of 2.54±5% mm and the tube is connected to a pressurization unit. When testing, the sample was dispensed under a pressure of 90 psi in 1 minute into a balance tray. The weight of sample dispensed in 1 minute was measured and recorded as flow rate value in Table 1 and 2. A larger flow rate value indicates greater flowability for the thermally conductive silicone adhesive composition and superior handling characteristics. The flow rate of more than 30 g/min is desired.

### Thermal Conductivity:

The compositions were cured at 125 °C for 1 hour. The thermal conductivity of cured samples was tested under temperature of 80 °C and pressure of 40 psi by LW 9389 manufactured by Longwin according to ASTM-D5470.

The thermal conductivity of no less than 8 W/m·K is desired in the present invention.

### Gap Stability Performance

The compositions were cured at 125 °C for 1 hour. The cured samples were tested under the following conditions (simulating challenging environment in application) respectively. The samples were judged as pass or fail based on the below criteria.

### (a) High Temperature Aging Test

The high temperature aging test was conducted by the thermal chamber PHH-102M manufactured by Espec under a high temperature of 125 °C for 1000 hours.

To determine reliability in high temperature aging test, pass/fail judgement was made by the following criteria:
Pass: no cracks were observed.
Fail: cracks were observed.

The results are shown in Table 1 and 2.

### (b) Thermal Circle Test

The thermal circle test was conducted by the thermal chamber TSE-12-A manufactured by Espec. Specifically, a cycle of 30-miniture low-temperature exposure at −40 °C and a 30-miniture high-temperature exposure at 125 °C was repeated 1000 times.

To determine reliability in thermal circle test, pass/fail judgement was made by the following criteria:
Pass: no cracks were observed.
Fail: cracks were observed.

The results are shown in Table 1 and 2.

### (c) “Double 85” Test

The “double 85” test was conducted by the thermal chamber LHU-213 manufactured by Espec under 85 °C in a humidity of 85% for 1000 hours.

To determine reliability in “double 85” test, pass/fail judgement was made by the following criteria:
Pass: no cracks were observed.
Fail: cracks were observed.

The results are shown in Table 1 and 2.

### Vibration and Shock Test

The compositions were cured at 125 °C for 1 hour. The cured samples were in a thickness of 1.0 mm and with a fixture roughness of 0.8~1.6 μm. The Vibration and Shock Test were conducted by GX-600-ZD manufactured by GAOXIN. The testing conditions are given below.

### <Vibration Condition>

Frequency: 1-200 Hz
Power spectral density: 0.0001-0.01 g²/Hz
Acceleration: 1.15GRMS
Directions and time: X/Y/Z, 30 mins.

### <Shock Condition>

Wave form: half sine
Acceleration: 10 g
Pulse width: 11 ms
Times: X/Y/Z 3 times in each of three directions.

To determine reliability in the vibration and shock test, pass/fail judgement was made by the following criteria:
Pass: the sample does not slip from the original position of the fixture.
Fail: the sample slips from the original position of the fixture.

The results are shown in Table 1 and 2.

### Examples 1 to 3 and Comparative Examples 1 to 5 (EX1 to EX3 and CE1 to CE5)

TABLE 1

| | CE1 | CE2 | CE3 | CE4 | CE5 | EX1 | EX2 | EX3 |
|---|---|---|---|---|---|---|---|---|
| (A) alkenyl group-containing | 1.75 | 1.75 | 1.75 | 1.75 | 1.75 | 1.75 | 1.75 | 1.75 |
| organopolysiloxane-1 | | | | | | | | |
| (B) chain-extender comprising | 0.24 | 0.24 | 0.41 | 0.78 | 0.78 | 0.41 | 0.55 | 0.67 |
| terminal silicon-hydride-1 | | | | | | | | |
| (C) cross-linker comprising | 0.13 | 0.13 | 0.11 | 0.03 | 0 | 0.11 | 0.08 | 0.06 |
| pendant silicon-hydride | | | | | | | | |
| (D) catalyst | 0.02 | 0.02 | 0.02 | 0.02 | 0.02 | 0.02 | 0.02 | 0.02 |
| (E) aluminum oxide-1 (D₅₀ = 0.3 μm) | 11 | 11 | 11 | 11 | 11 | 11 | 11 | 11 |
| (E) aluminum nitride-1 (D₅₀ = 1.5 μm) | 9 | 9 | 9 | 9 | 9 | 9 | 9 | 9 |
| (E) aluminum oxide-2 (D₅₀ = 5 μm) | 21 | 21 | 21 | 21 | 21 | 21 | 21 | 21 |
| (E) aluminum oxide-3 (D₅₀ = 20 μm) | 14 | 14 | 14 | 14 | 14 | 14 | 14 | 14 |
| (E) aluminum nitride-2 (D₅₀ = 100 μm) | 40.5 | 40.5 | 40.5 | 40.5 | 40.5 | 40.5 | 40.5 | 40.5 |
| (F) core-shell particle-1 | 0 | 0.3 | 0 | 0.3 | 0.3 | 0.3 | 0.3 | 0.3 |
| Dimethylpolysiloxane | 1.855 | 1.645 | 1.705 | 1.115 | 1.145 | 1.405 | 1.295 | 1.195 |
| Filler treatment agent | 0.5 | 0.5 | 0.5 | 0.5 | 0.5 | 0.5 | 0.5 | 0.5 |
| Inhibitor | 0.005 | 0.005 | 0.005 | 0.005 | 0.005 | 0.005 | 0.005 | 0.005 |
| Total weight | 100 | 100.09 | 100 | 100 | 100 | 100 | 100 | 100 |
| mole ratio of (B) to (C) | 1:1 | 1:1 | 2:1 | 10:1 | 0 | 2:1 | 4:1 | 6:1 |
| Testing results | | | | | | | | |
| Flow rate(g/min) | 45 | 42 | 46 | 45 | 48 | 46 | 44 | 48 |
| Thermal conductivity/(W/m · K) | 8.51 | 8.55 | 8.46 | 8.48 | 8.42 | 8.46 | 8.48 | 8.42 |
| Gap stability performance | | | | | | | | |
| (a) High temperature aging test | Pass | Pass | Pass | Pass | Pass | Pass | Pass | Pass |
| (b) Thermal circle test | Fail | Pass | Fail | Fail | Fail | Pass | Pass | Pass |
| (c) Double 85 test | Fail | Pass | Pass | Fail | Fail | Pass | Pass | Pass |
| Vibration and Shock test | Fail | Fail | Pass | Pass | Pass | Pass | Pass | Pass |

As indicated in Table 1, a comparison between CE1, CE3 and Ex1 reveals that the introduction of core-shell polymer particles significantly enhances the stability of the gap in the samples. Notably, even a small quantity of core-shell particles contributes to this improvement. Furthermore, when comparing CE2, CE4, CE5, Ex1, Ex2 and Ex3, it becomes evident that maintaining the mole ratio between component (B) and component (C) within the specified range according to the present invention, leads to improved gap stability, and successfully passes the Vibration and Shock Test.

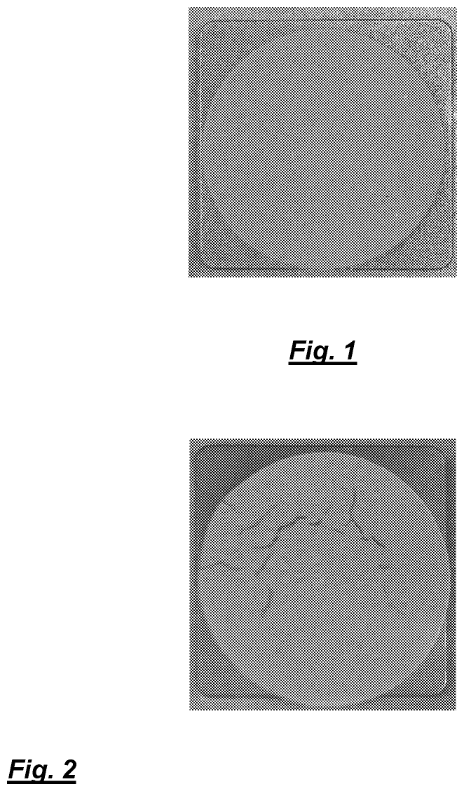

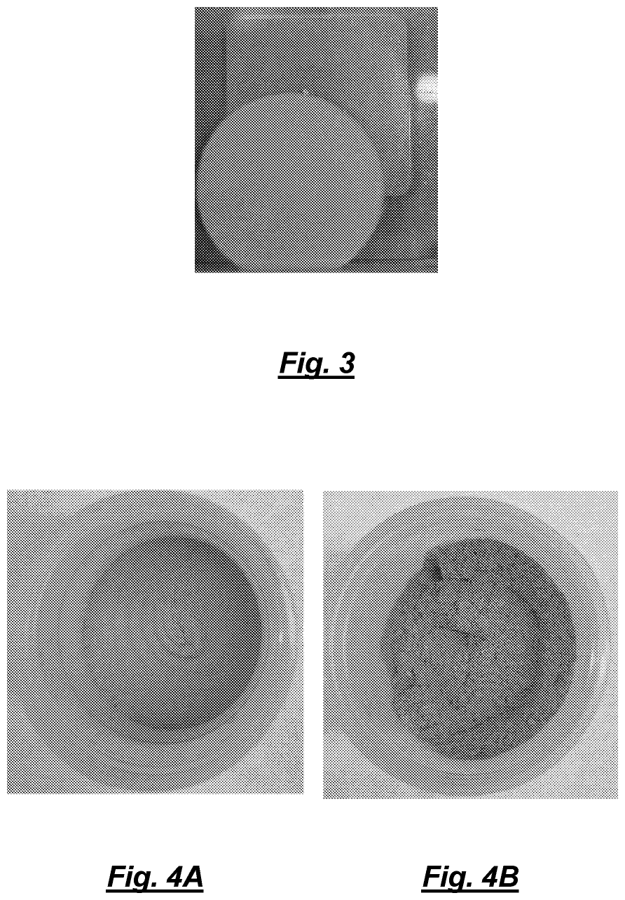

From comparing FIG. 1 and FIG. 2, it can be seen that in the thermal cycle test, the Ex1 can withstand the challenge of high-temperature aging without any cracks. In contrast, CE3, which exhibited cracks, would fail during application and lacks reliability. And FIG. 3 clearly shows that CE2 slipped from the original position during vibration and shock test.

### Examples 4 to 7 and Comparative Example 6 (EX4 to EX7 and CE6)

TABLE 2

| | EX4 | EX5 | EX6 | EX7 | EX8 | CE6 |
|---|---|---|---|---|---|---|
| (A) alkenyl group-containing | 1.875 | 1.875 | 1.875 | 1.875 | 1.875 | 1.875 |
| organopolysiloxane-2 | | | | | | |
| (B) chain-extender comprising | 0.35 | 0.35 | 0.35 | 0.35 | 0.35 | 0.35 |
| terminal silicon-hydride-2 | | | | | | |
| (C) cross-linker comprising | 0.35 | 0.35 | 0.35 | 0.35 | 0.35 | 0.35 |
| pendant silicon-hydride | | | | | | |
| (D) catalyst | 0.02 | 0.02 | 0.02 | 0.02 | 0.02 | 0.02 |
| (E) aluminum oxide-1 (D₅₀ = 0.3 μm) | 11 | 11 | 11 | 11 | 11 | 0 |
| (E) aluminum nitride-1 (D₅₀ = 1.5 μm) | 9 | 9 | 9 | 9 | 9 | 9 |
| (E) aluminum oxide-2 (D₅₀ = 5 μm) | 21 | 21 | 21 | 21 | 21 | 21 |
| (E) aluminum oxide-3 (D₅₀ = 20 μm) | 14 | 14 | 14 | 14 | 14 | 14 |
| (E) aluminum nitride-2 (D₅₀ = 100 μm) | 40.5 | 40.5 | 40.5 | 40.5 | 40.5 | 40.5 |
| Silica | 0 | 0 | 0 | 0 | 0 | 11 |
| (F) Core-shell particle-1 | 0.2 | 0.3 | 0.5 | 0 | 0 | 0.3 |
| (F) Core-shell particle-2 | 0 | 0 | 0 | 0.3 | 0 | 0 |
| (F) Core-shell particle-3 | 0 | 0 | 0 | 0 | 0.3 | 0 |
| Dimethylpolysiloxane | 1.2 | 1.1 | 0.9 | 1.1 | 1.1 | 0.7 |
| Filler treatment agent | 0.5 | 0.5 | 0.5 | 0.5 | 0.5 | 0.5 |
| Inhibitor | 0.005 | 0.005 | 0.005 | 0.005 | 0.005 | 0.005 |
| Total weight | 100 | 100 | 100 | 100 | 100 | 100 |
| mole ratio of (B) to (C) | 2:1 | 2:1 | 2:1 | 2:1 | 2:1 | 2:1 |
| Test results | | | | | | |
| Flow rate(g/min) | 36 | 35 | 31 | 33 | 35 | N/A |
| Thermal conductivity/(W/m · K) | 8.52 | 8.57 | 8.62 | 8.53 | 8.56 | N/A |
| Gap stability performance | | | | | | |
| (a) High temperature aging test | Pass | Pass | Pass | Pass | Pass | N/A |
| (b) Thermal circle test | Pass | Pass | Pass | Pass | Pass | N/A |
| (c) Double 85 test | Pass | Pass | Pass | Pass | Pass | N/A |
| Vibration and Shock Test | Pass | Pass | Pass | Pass | Pass | N/A |

N/A indicates the inability to attain a homogeneous mixture, thereby precluding the subsequent curing and testing processes.

As indicating in Table 2, it is evident that the incorporation of core-shell polymer particles within the specified range outlined in the present application enhances both gap stability and achieves the desired flow rate.

In the comparison between CE6 and Ex5, silica is not suitable thermal conductive filler in the present application. FIGS. 4A and 4B clearly shows that introducing silica into the thermal conductive silicone composition of the present invention cannot obtain homogeneous mixture with flowability.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. A thermally conductive silicone adhesive composition comprising:
(A) at least one alkenyl group-containing organopolysiloxane,
(B) at least one chain-extender comprising terminal silicon-hydride,
(C) at least one cross-linker comprising pendant silicon-hydride,
(D) at least one catalyst,
(E) at least one thermal conductive filler selected from aluminum oxide, aluminum nitride and combinations thereof, and
(F) at least one core-shell solid polymer particle;
wherein the composition has a mole ratio of component (B) to component (C) of from more than 1:1 to less than 10:1.

2. The thermally conductive silicone adhesive composition according to claim 1, wherein the component (B) has a structural formula: 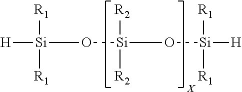
wherein R₁ each independently represents a substituted or unsubstituted alkyl group, aryl group, or hydrocarbon group having carbon atoms of from 1 to 3, R₂ each independently represents a substituted or unsubstituted alkyl group, aryl group, or hydrocarbon group having carbon atoms of from 1 to 10, and X represents an integer of from 0 to 5000.

3. The thermally conductive silicone adhesive composition according to claim 1, wherein the component (C) has a structural formula: 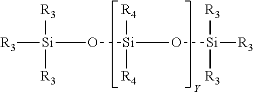
wherein R₃ each independently represents a substituted or unsubstituted alkyl group, aryl group, or hydrocarbon group having carbon atoms of from 1 to 3, R₄ each independently represents hydrogen, a substituted or unsubstituted alkyl group, aryl group, or hydrocarbon group having carbon atoms of from 1 to 10 provided that at least two of the R₄ are hydrogens, and Y represents an integer of from 0 to 5000.

4. The thermally conductive silicone adhesive composition according to claim 1, wherein the component (D) is a platinum-based catalyst.

5. The thermally conductive silicone adhesive composition according to claim 1, wherein the component (E) comprises:
(e-1) aluminum oxide and/or aluminum nitride filler having a D50 particle size of from 50 μm to 200 μm,
(e-2) aluminum oxide and/or aluminum nitride filler having a D50 particle size of from no less than 10 to 30 μm,
(e-3) aluminum oxide and/or aluminum nitride filler having a D50 particle size of from 5 to 10 μm, and
(e-4) aluminum oxide and/or aluminum nitride filler having a D50 particle size less than 5 μm.

6. The thermally conductive silicone adhesive composition according to claim 1, wherein the component (F) has a soft core formed by a polymer having a Tg of less than 0 °C and a hard shell formed by a polymer having a Tg of no less than 0 °C.

7. The thermally conductive silicone adhesive composition according to claim 6, wherein
the polymer of the soft core is a homopolymer or copolymer formed from monomers selected from dienes, alkyl (meth)acrylates, silicone rubbers, styrenics and mixtures thereof, and/or
the polymer of the hard shell is a homopolymer or copolymer formed from monomers selected from methacrylates, acrylates, styrenics and mixtures thereof.

8. The thermally conductive silicone adhesive composition according to claim 1, wherein the composition further comprises a non-reactive organopolysiloxane.

9. The thermally conductive silicone adhesive composition according to claim 1, wherein the composition further comprises an inhibitor.

10. The thermally conductive silicone adhesive composition according to claim 1, wherein the mole ratio of component (B) to component (C) is from 2:1 to 8:1.

11. A cured product made from the composition according to claim 1.

12. A method for preparing a thermally conductive gap filler, comprising.
(i) mixing the following components to form a mixture:
(A) at least one alkenyl group-containing organopolysiloxane;
(B) at least one chain-extender comprising terminal silicon-hydride;
(C) at least one cross-linker comprising pendant silicon-hydride;
(D) at least one catalyst;
(E) at least one thermal conductive filler selected from aluminum oxide, aluminum nitride or a combination thereof;
(F) a core-shell solid polymer particle; and
other optional components,
(ii) allowing the mixture to cure.

13. The method according to claim 12, wherein the cure is conducted at room temperature or at elevated temperature from 60 °C to 200 °C.

14. An article comprising the cured product made from the composition according to claim 1.

15. A thermally conductive gap filler made according to the method of claim 13 exhibiting thermal conductivity of >8 W/m·K.

16. An electronic device comprising the thermally conductive gap filler of claim 15.
